(19) United States
(12) Patent Application Publication
(10) Pub. No.: US 2013/0233599 A1
(43) Pub. Date: Sep. 12, 2013

(54) SUBSTRATE FOR POWER MODULE

(71) Applicants: Kwang Soo Kim, Gyunggi-do (KR); Young Ki Lee, Gyunggi-do (KR); Bum Seok Suh, Gyunggi-do (KR)

(72) Inventors: Kwang Soo Kim, Gyunggi-do (KR); Young Ki Lee, Gyunggi-do (KR); Bum Seok Suh, Gyunggi-do (KR)

(73) Assignee: SAMSUNG ELECTRO-MECHANICS CO., LTD., Gyunggi-do (KR)

(21) Appl. No.: 13/484,188

(22) Filed: May 30, 2012

(30) Foreign Application Priority Data
Mar. 8, 2012 (KR) 1020120024043

(51) Int. Cl. H05K 1/05

(52) U.S. Cl. 174/255

(57) ABSTRACT

Disclosed herein is a substrate for a power module. The substrate may include a metal base substrate, an insulating layer formed on the metal base substrate and including a plurality of insulating adhesion layers and a ceramic filler layer formed on a joining interface between the plurality of insulating adhesion layers, and a circuit layer formed on the insulating layer.

### CROSS REFERENCE TO RELATED APPLICATION

This application claims the benefit of Korean Patent Application No. 10-2012-0024043, filed on Mar. 8, 2012, entitled “Substrate for Power Module”, which is hereby incorporated by reference in its entirety into this application.

### BACKGROUND OF THE INVENTION

1. Technical Field

The present invention relates to a substrate for a power module.

2. Description of the Related Art

With an increase in energy consumption amount all over the world, significant interest for efficient use of limited energy has emerged. Accordingly, an inverter to which an Intelligent Power Module (IPM) for efficient conversion of energy in existing consumer/industrial products is applied has been adopted in an accelerated manner.

Meanwhile, as disclosed in Patent Document 1, as a power module having a variety of structures has been increasingly applied, the market requires higher integration, higher capacity, and miniaturization of the power module. As a result, the higher integration of the power module causes problems such as heat generation in electronic components and deterioration in performance of the overall module.

Therefore, in order to secure increased efficiency and high reliability of the power module, there is a demand for a high-heat dissipation package structure for overcoming the above-mentioned problems such as the heat generation.

[Patent Document]

(Patent Document 1) U.S. Pat. No. 6,432,750 B Aug. 13, 2002.

### SUMMARY OF THE INVENTION

The present invention has been made in an effort to provide a substrate for a power module which may improve heat dissipation efficiency due to high thermal conductivity.

According to a preferred embodiment of the present invention, there is provided a substrate for a power module, including: a metal base substrate; an insulating layer formed on the metal base substrate, and including a plurality of insulating adhesion layers and a ceramic filler layer formed on a joining interface between the plurality of insulating adhesion layers; and a circuit layer formed on the insulating layer.

Here, the ceramic filler layer may be formed in a manner such that a ceramic filler is uniformly formed on the entire surface of the joining interface between the plurality of insulating adhesion layers.

Also, a content of the ceramic filler contained in the ceramic filler layer may be 80% to 93%.

In addition, the ceramic filter may be selected from the group consisting of aluminum oxide (Al₂O₃), aluminum nitride (AIN), boron nitride (BN), silicon dioxide (SiO₂), silicon carbide (SiC) or a combination thereof.

Also, the ceramic filler layer may be formed in a manner such that a ceramic filler disposed on the same plane is infiltrated into the insulating adhesion layer adjacent to the ceramic filler.

Also, the insulating adhesion layer may be selected from the group consisting of prepreg, epoxy, poly imide, a liquid crystal polymer, or a combination thereof.

Also, the metal base substrate may be made of aluminum (Al), copper (Cu), iron (Fe), or titanium (Ti).

According to another preferred embodiment of the present invention, there is provided a substrate for a power module, including: a metal base substrate; an insulating layer formed on the metal base substrate, and including a plurality of insulating adhesion layers and a ceramic filler layer formed on a joining interface between the plurality of insulating adhesion layers; and a circuit layer formed on the insulating layer, wherein the plurality of insulating adhesion layers includes a first ceramic filler.

Here, the ceramic filler layer may be formed in a manner such that a second ceramic filler is uniformly formed on the entire surface of the joining interface between the plurality of insulating adhesion layers.

In addition, a content of the second ceramic filler contained in the ceramic filler layer may be 80% to 93%.

Also, the first and second ceramic fillers may be selected from the group consisting of aluminum oxide (Al₂O₃), aluminum nitride (AIN), boron nitride (BN), silicon dioxide (SiO₂), silicon carbide (SiC) or a combination thereof.

Also, a particle size of the first ceramic filler may be smaller than that of the second ceramic filler.

Also, the ceramic filler layer may be formed in a manner such that the ceramic filler disposed on the same plane is infiltrated into the insulating adhesion layer adjacent to the ceramic filler.

Also, the insulating adhesion layer may be selected from the group consisting of prepreg, epoxy, poly imide, a liquid crystal polymer, or a combination thereof.

Also, the metal base substrate may be made of aluminum (Al), copper (Cu), iron (Fe), or titanium (Ti).

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional diagram illustrating a configuration of a substrate for a power module according to an embodiment of the present invention;

FIGS. 2 and 3 are cross-sectional diagrams illustrating a first embodiment of an insulating layer of FIG. 1, in detail;

FIGS. 4 and 5 are cross-sectional diagrams illustrating a second embodiment of an insulating layer of FIG. 1, in detail; and

FIGS. 6 and 7 are diagrams illustrating experimental data for a content of a ceramic filler according to an embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the prior art would obscure the gist of the present invention, the description thereof will be omitted.

Hereinafter, preferred embodiments of the present invention will be described in detail with reference to the attached drawings.

### Substrate for Power Module—First Embodiment

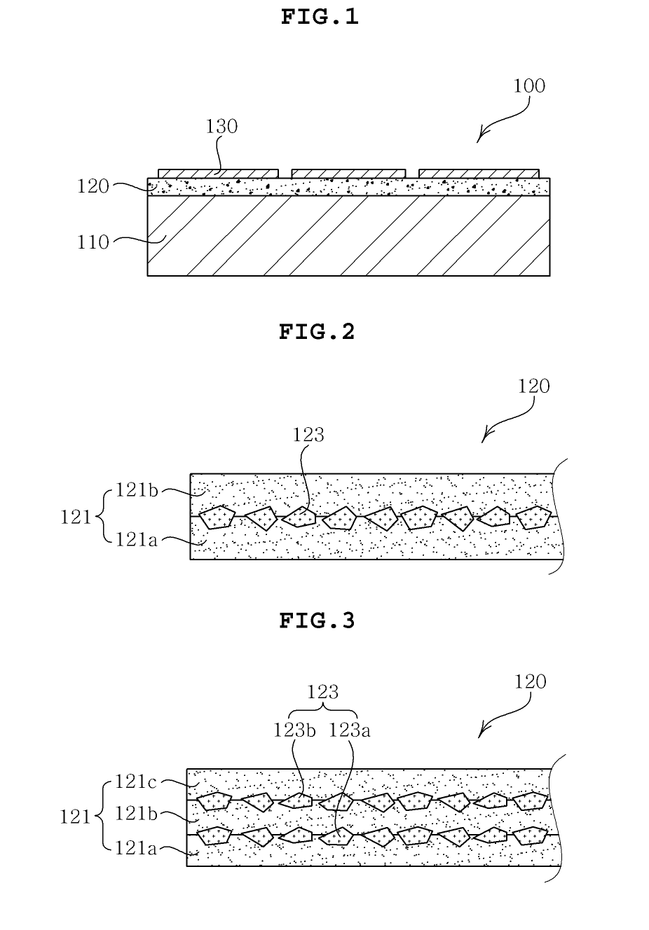

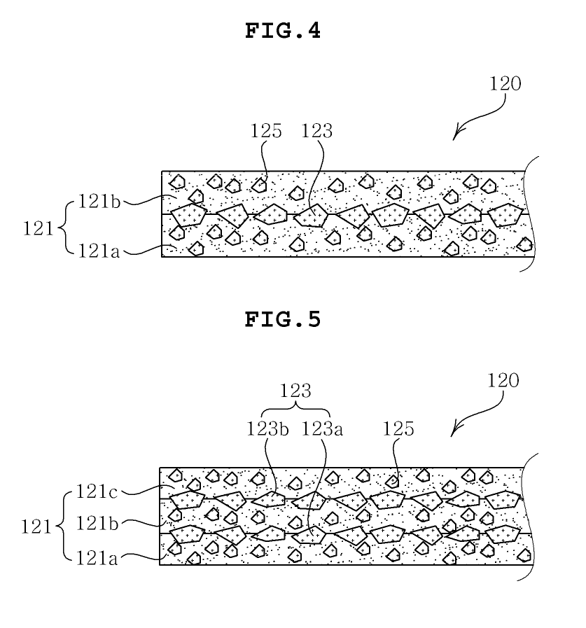

FIG. 1 is a cross-sectional diagram illustrating a configuration of a substrate for a power module according to an embodiment of the present invention, and FIGS. 2 and 3 are cross-sectional diagrams illustrating a first embodiment of an insulating layer of FIG. 1, in detail.

As illustrated in FIGS. 1 through 3, a substrate 100 for a power module may include a metal base substrate 110, an insulating layer 120 formed on the metal base substrate 110, and a circuit layer 130 formed on the insulating layer 120. Here, the insulating layer 120 includes a plurality of insulating adhesion layers 121a, 121b, and 121c (hereinafter, referred to as “121”) and ceramic filler layers 123, 123a, and 123b which are formed on a joining interface between the plurality of insulating adhesion layers 121.

Here, the metal base substrate 110 may be made of aluminum (Al), copper (Cu), iron (Fe), or titanium (Ti), and the present invention is not limited thereto.

In addition, the metal base substrate 110 may be processed to have various thicknesses and sizes depending on the uses.

In this instance, since the metal base substrate 110 is formed to have various thicknesses, a lead frame which does not use a down-set structure may be applied, thereby significantly improving proccessability.

In addition, as illustrated in FIGS. 2 and 3, the insulating layer 120 is formed in a manner such that a first insulating adhesion layer 121a is formed, coating of the ceramic filler is uniformly applied on the entire surface of the first insulating adhesion layer 121a, and a second insulating adhesion layer 121b is laminated on the first insulating adhesion layer 121a coated with the ceramic filler.

In this instance, the insulating adhesion layers 121, 121a, and 121b may be selected from the group consisting of prepreg, epoxy, poly imide, a liquid crystal polymer, or a combination thereof.

In addition, as a method of applying coating of the ceramic filler on the insulating adhesion layer, a spray method of applying coating of ceramic particles by spray, a static method in which ceramic filler particles are attached on a polymer film by static by charging the polymer film, and then the polymer film is transferred on the first insulating adhesion layer, or a prepreg joining method of joining a prepreg film so that a content of the ceramic filler is 80% to 93% may be applied.

A thickness of each of the insulating adhesion layers 121, 121a, and 121b may be determined according to the number of insulating adhesion layers to be laminated, and the number of arranged ceramic filler layers to be laminated.

As illustrated in FIGS. 2 and 3, the ceramic filler layer 123 may be formed in a manner such that the ceramic filler disposed on the same plane is infiltrated into the insulating adhesion layer (for example, the first insulating adhesion layer 121a or the second insulating adhesion layer 121b) adjacent to the ceramic filler.

The ceramic filler layer 123 may be composed of a single layer 123 as illustrated in FIG. 2, or a plurality of layers 123a and 123b equal to or more than two layers as illustrated in FIG. 3.

In addition, the ceramic filler layer 123 may be formed in a manner such that the ceramic filler is uniformly formed on the entire surface of the joining interface between the plurality of insulating adhesion layers 121.

In this instance, a content of the ceramic filler contained in the ceramic filler layer 123 may be 80% to 93%. That is, 80% to 93% of the ceramic filler may be contained in the ceramic filler layer 123 in comparison with the insulating adhesion layer formed on the same plane.

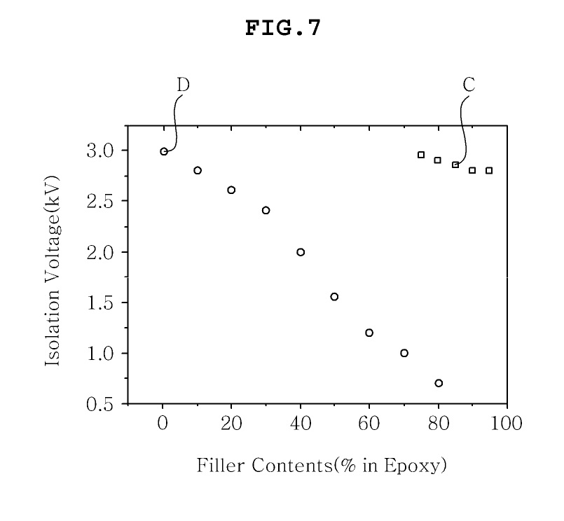

Meanwhile, as illustrated in FIG. 6, according to an embodiment of the present invention, even when the content of the ceramic filler (uniformly formed on the same plane) contained in an insulating material (for example, epoxy) is 80% to 93% (see, A of FIG. 6), adhesion equal to or greater than 1.2 kgf that is an adhesion reference value between a metal and an insulating material during a process of manufacturing a substrate may be maintained, and a change in the adhesion due to an increase in the content of the ceramic filler may be barely perceptible, thereby securing reliability.

In contrast, in the prior art (see, B of FIG. 6), it has been found that the adhesion is dramatically reduced along with an increase in the content of the ceramic filler contained in the insulating material, such that the adhesion is reduced to 1.2 kgf, which is the adhesion reference value, or below.

In addition, as illustrated in FIG. 7, according to an embodiment of the present invention, even when the content of the ceramic filler (uniformly formed on the same plane) contained in the insulating material (for example, epoxy) is 80% to 93% (see, C of FIG. 7), an isolation voltage equal to or greater than 2.5 kV which is greater than 1.5 kV that is a reference value for applying the substrate 100 to the power module may be secured.

In contrast, in the prior art (see, D of FIG. 7), the isolation voltage is dramatically reduced along with the increase in the content of the ceramic filler contained in the insulating material, such that the isolation voltage is reduced to 1.5 kV, which is the reference value, or below. As a result, the substrate 100 cannot be applied to the power module.

As described above, the substrate 100 for the power module according to the present invention may be applied to the power module although the content of the ceramic filler is increased, and therefore, improvement in heat dissipation characteristics due to the ceramic filler, and miniaturization, high integration, and high capacity of a power module package may be achieved.

In addition, the ceramic filler may be selected from the group consisting of aluminum oxide (Al₂O₃), aluminum nitride (AIN), boron nitride (BN), silicon dioxide (SiO₂), silicon carbide (SiC) or a combination thereof, and the present invention is not limited thereto.

In addition, the circuit layer 130 may be formed on the insulating layer 120, and a sand blast method, a chemical etching method, or a buffing method may be applied to a copper (Cu) foil in the joining interface side so as to increase a joining strength with the insulating layer.

In addition, the above described metal base substrate 110, the insulating layer 120, and the circuit layer 130 may be joined using a high-temperature and high-pressure press method, and the present invention is not limited thereto.

### Substrate for Power Module—Second Embodiment

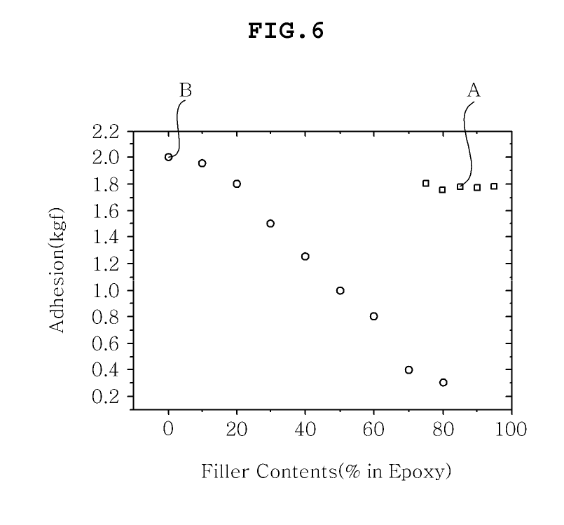

FIGS. 4 and 5 are cross-sectional diagrams illustrating a second embodiment of an insulating layer of FIG. 1, and the second embodiment will be described with reference to FIG. 1.

However, the same configuration as that of the first embodiment will be omitted, and only a configuration different from above will be described.

As illustrated in FIGS. 1, 4, and 5, the substrate 100 for the power module may include the metal base substrate 110, the insulating layer 120 formed on the metal base substrate 110, and the circuit layer 130 formed on the insulating layer 120. Here, the insulating layer 120 may include the plurality of insulating adhesion layers 121a, 121b, and 121c (hereinafter, referred to as “121”) and the ceramic filler layers 123, 123a, and 123b formed on the joining interface between the plurality of insulating adhesion layers 121.

In this instance, the plurality of insulating adhesion layers 121 may include a first ceramic filler 125.

In addition, the metal base substrate 110 may be made of aluminum (Al), copper (Cu), iron (Fe), or titanium (Ti).

In addition, the insulating adhesion layer 121 may be selected from the group consisting of prepreg, epoxy, poly imide, a liquid crystal polymer, or a combination thereof.

In addition, the ceramic filler layer 123 may be formed in a manner such that a second ceramic filler is uniformly formed on the entire surface of the joining interface between the plurality of insulating adhesion layers 121.

In this instance, a content of the ceramic filler contained in the ceramic filler layer 123 may be 80% to 93%.

In addition, the first and second ceramic fillers may be selected from the group consisting of aluminum oxide (Al₂O₃), aluminum nitride (AIN), boron nitride (BN), silicon dioxide (SiO₂), silicon carbide (SiC) or a combination thereof.

In addition, as illustrated in FIGS. 4 and 5, the ceramic filler layer 123 may be formed in a manner such that the ceramic filler disposed on the same plane is infiltrated into the insulating adhesion layer 121 adjacent to the ceramic filler.

The ceramic filler layer 123 may be composed of a single layer 123 as illustrated in FIG. 4, or a plurality of layers 123a and 123b equal to or more than two layers as illustrated in FIG. 5.

In addition, a particle size of the first ceramic filler 125 may be smaller than that of the second ceramic filler (filler contained in the ceramic filler layer 123).

The substrate 100 for the power module according to the embodiments of the present invention may have excellent heat dissipation characteristics, so that heat generation of an element having large heat generation such as a power element may be effectively removed when the substrate 100 is applied to a power module package. Therefore, effects on a control element which is vulnerable to heat may be minimized, thereby improving reliability of products and driving characteristics over a life span.

In addition, the substrate 100 for the power module according to the embodiments of the present invention may control the metal base substrate of a Copper Bonded Metal (CBM) substrate to have various thicknesses, so that a lead frame may be used without applying a down-set structure, thereby significantly improving module manufacturing proccessability.

In addition, according to the embodiments of the present invention, formation of free metal circuit wiring is made possible on the substrate for the power module, thereby significantly improving the degree of freedom in design of a module.

As described above, the substrate for the power module according to the embodiments of the present invention may adopt the base substrate made of a metal and the plurality of ceramic filler layers, so that heat generated from the power module may be effectively conducted through the ceramic filler layer, thereby improving heat dissipation characteristics of the substrate for the power module.

In addition, according to the embodiments of the present invention, the insulating layer may be composed of the plurality of ceramic filler layers, so that the substrate for the power module in which miniaturization and improved heat dissipation characteristics are achieved may be implemented through a simple process in comparison with the prior art of forming a separate heat dissipation substrate.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A substrate for a power module, comprising:
a metal base substrate;
an insulating layer formed on the metal base substrate, and including a plurality of insulating adhesion layers and a ceramic filler layer formed on a joining interface between the plurality of insulating adhesion layers; and
a circuit layer formed on the insulating layer.

2. The substrate for the power module as set forth in claim 1, wherein the ceramic filler layer is formed in a manner such that a ceramic filler is uniformly formed on the entire surface of the joining interface between the plurality of insulating adhesion layers.

3. The substrate for the power module as set forth in claim 2, wherein a content of the ceramic filler contained in the ceramic filler layer is 80% to 93%.

4. The substrate for the power module as set forth in claim 2, wherein the ceramic filter is selected from the group consisting of aluminum oxide (Al₂O₃), aluminum nitride (AIN), boron nitride (BN), silicon dioxide (SiO₂), silicon carbide (SiC) or a combination thereof.

5. The substrate for the power module as set forth in claim 1, wherein the ceramic filler layer is formed in a manner such that a ceramic filler disposed on the same plane is infiltrated into the insulating adhesion layer adjacent to the ceramic filler.

6. The substrate for the power module as set forth in claim 1, wherein the insulating adhesion layer is selected from the group consisting of prepreg, epoxy, poly imide, a liquid crystal polymer, or a combination thereof.

7. The substrate for the power module as set forth in claim 1, wherein the metal base substrate is made of aluminum (Al), copper (Cu), iron (Fe), or titanium (Ti).

8. A substrate for a power module, comprising:
a metal base substrate;
an insulating layer formed on the metal base substrate, and including a plurality of insulating adhesion layers and a ceramic filler layer formed on a joining interface between the plurality of insulating adhesion layers; and
a circuit layer formed on the insulating layer,
wherein the plurality of insulating adhesion layers includes a first ceramic filler.

9. The substrate for the power module as set forth in claim 8, wherein the ceramic filler layer is formed in a manner such that a second ceramic filler is uniformly formed on the entire surface of the joining interface between the plurality of insulating adhesion layers.

10. The substrate for the power module as set forth in claim 9, wherein a content of the second ceramic filler contained in the ceramic filler layer is 80% to 93%.

11. The substrate for the power module as set forth in claim 9, wherein the first and second ceramic fillers are selected from the group consisting of aluminum oxide (Al₂O₃), aluminum nitride (AIN), boron nitride (BN), silicon dioxide (SiO₂), silicon carbide (SiC) or a combination thereof.

12. The substrate for the power module as set forth in claim 9, wherein a particle size of the first ceramic filler is smaller than that of the second ceramic filler.

13. The substrate for the power module as set forth in claim 8, wherein the ceramic filler layer is formed in a manner such that the ceramic filler disposed on the same plane is infiltrated into the insulating adhesion layer adjacent to the ceramic filler.

14. The substrate for the power module as set forth in claim 8, wherein the insulating adhesion layer is selected from the group consisting of prepreg, epoxy, poly imide, a liquid crystal polymer, or a combination thereof.

15. The substrate for the power module as set forth in claim 8, wherein the metal base substrate is made of aluminum (Al), copper (Cu), iron (Fe), or titanium (Ti).
